(19) United States
(12) Patent Application Publication
(10) Pub. No.: US 2010/0308296 A1
(43) Pub. Date: Dec. 9, 2010

(54) PHASE CHANGE MEMORY CELL WITH SELF-ALIGNED VERTICAL HEATER

(76) Inventors: Agostino Pirovano, Corbetta (IT); Giorgio Servalli, Ciserano (IT); Fabio Pellizzer, Cornate d'Adda (IT); Andrea Redaelli, Lecco (IT)

Correspondence Address: Gerbera/BSTZ;Blakely Sokoloff Taylor & Zafman LLP, 1279 OAKMEAD PARKWAY, SUNNYVALE, CA, 94085, US

(21) Appl. No.: 12/481,496

(22) Filed: Jun. 9, 2009

(51) Int. Cl. H01L 45/00; H01L 21/28

(52) U.S. Cl. 257/5; 438/329; 257/E45.002; 257/E21.158

(57) ABSTRACT

A self-aligned vertical heater element is deposited directly on the silicide of a selection device, and a phase change chalcogenide material is deposited directly on the vertical heater element. The fabrication process allows for self-alignment between the chalcogenide line and vertical heater element. In an embodiment, the vertical heater element is L-shaped, having a vertical wall along the wordline direction and a horizontal base. The vertical wall and the horizontal base may have the same thickness.

### BACKGROUND

Embodiments of the invention relate to a process for manufacturing a phase change memory cell with fully self-aligned vertical heater elements.

Phase change memories are formed by memory cells connected at the intersections of bitlines and wordlines and comprising each a memory element and a selection element. A memory element comprises a phase change region made of a phase change material, i.e., a material that may be electrically switched between a generally amorphous and a generally crystalline state across the entire spectrum between completely amorphous and completely crystalline states.

Typical materials suitable for the phase change region of the memory elements include various chalcogenide elements. The state of the phase change materials is non-volatile, absent application of excess temperatures, such as those in excess of 150° C., for extended times. When the memory is set in either a crystalline, semi-crystalline, amorphous, or semi-amorphous state representing a resistance value, that value is retained until reprogrammed, even if power is removed.

Selection elements may be formed according to different technologies. For example, they can be implemented by diodes, metal oxide semiconductor (MOS) transistors or bipolar transistors. Heater elements are supplied in connection with the selection elements in order to provide heat to the chalcogenide elements.

### BRIEF DESCRIPTION OF THE DRAWINGS

FIG. 1 is an isometric view of a pnp-BJT array in accordance with an embodiment.

FIG. 2 is an isometric view of vertical heater elements disposed on a row of emitter pillars in the x-direction of the pnp-BJT array of FIG. 1.

FIG. 3 is a cross-sectional illustration along the x-direction (parallel to the wordline direction) and the y-direction (parallel to the bitline direction) of the pnp-BJT array of FIG. 1.

FIG. 4 is a cross-sectional illustration of a dielectric layer blanket deposited over the pnp-BJT array of FIG. 3.

FIG. 5 is a cross-sectional illustration of a conformal conductive layer deposited over the pnp-BJT array of FIG. 4.

FIG. 6 is a cross-sectional illustration of a conformal dielectric layer deposited over the conformal conductive layer of FIG. 5.

FIG. 7 is a cross-sectional illustration of the conformal dielectric layer and conformal conductive layer of FIG. 6 anisotropically etched back.

FIG. 8 is a cross-sectional illustration of a dielectric layer deposited over the pnp-BJT array and within the trenches of FIG. 7 and planarized.

FIG. 9 is a cross-sectional illustration of a phase change layer and metallic cap layer deposited over the structure in FIG. 8.

FIG. 10 is an illustration of anisotropically etching lines in the y-direction.

FIG. 11 is an illustration of back end of the line (BEOL) metallization in accordance with an embodiment.

FIG. 12 is an illustration of a system in accordance with an embodiment.

### DETAILED DESCRIPTION

Embodiments of the invention relate to a phase change memory cell with fully self-aligned vertical heater elements and process for manufacturing the same.

Various embodiments described herein are described with reference to figures. However, certain embodiments may be practiced without one or more of these specific details, or in combination with other known methods and configurations. Reference throughout this specification to “one embodiment” or “an embodiment” means that a particular feature, configuration, composition, or characteristic described in connection with the embodiment is included in at least one embodiment of the invention. Thus, the appearances of the phrase “in one embodiment” or “an embodiment” in various places throughout this specification are not necessarily referring to the same embodiment of the invention. Furthermore, the particular features, configurations, compositions, or characteristics may be combined in any suitable manner in one or more embodiments.

Embodiments of the invention disclose a phase change memory cell including a self-aligned vertical heater element deposited directly on a silicide contact region of a selection element, and a phase change material deposited directly on the vertical heater element. In an embodiment, the selection element is a vertical pnp bipolar junction transistor (BJT) and the vertical heater element is L-shaped, having a vertical wall extending along the wordline direction and a horizontal base orthogonal to the vertical wall. The self-aligned fabrication process allows for controlled alignment of the vertical wall to the bitline direction of the phase change memory cell, as well as the controlled alignment between the phase change material and heater element. The vertical wall and the horizontal base may have the same thickness.

In one embodiment, a pnp-BJT array includes emitter pillars having a width and depth of F×F, with F being the lithographic node. For example, utilizing 193 nm immersion lithography, the width and depth of the emitter pillars is approximately 50 nm. In such an embodiment, the L-shaped vertical heater element may have a thickness of between 5-10 nm and a height between 50-150 nm. In an embodiment, the vertical wall portion has an aspect ratio of at least 5:1 height:width.

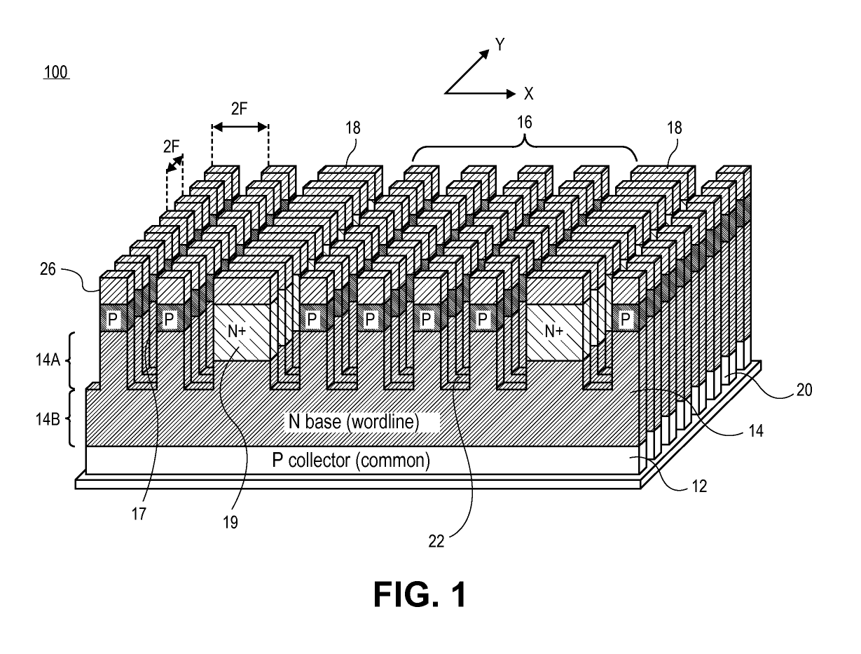

FIG. 1 is an isometric view of a pnp-BJT array 100 in accordance with an embodiment. As shown in FIG. 1, the array includes four columns of emitter pillars 16 shared by one column of base contact pillars 18. Each set of emitter columns 16 is separated by a column of a wider base contact column 18. Dielectrics that fill all the regions for isolation among the pillars are transparent in the illustration. A semiconductor substrate is doped with a p-type dopant to form the p-type collector (common) 12 under a shallower base dopant that forms an n-type wordline 14 including upper part 14a and lower part 14b.

Each row of emitter pillars 16 is separated from an adjacent row in the x-direction by shallow trench isolation 22. Likewise, each column of emitter pillars 16 is separated from adjacent emitter pillars 16 in the y-direction by shallow trench isolation 20. The shallow trench isolations 22 may be shallower than the shallow trench isolations 20. The deeper shallow trench isolations 20 may extend all the way into the p-type collector 12 while the shallow trench isolations 22 may extend only into the n-type wordline 14. Thus, the n-type wordline 14 is made up of a lower part 14b which is below the shallow trench isolations 22, and an upper part 14a which is above the bottom of shallow trench isolations 20.

The base contacts 18 are n+base contacts, the emitters 16 are p-type, and the wordline is n-type. Silicide contact regions 26 are formed on top of p+ emitter regions 17 and n+ base regions 19. A BJT transistor is formed with an emitter 16, base contact 18, wordline 14, and collector 12. The wordline 14 is common to each row in the x-direction. The collector 12 is common to all the transistors. In certain embodiments, the polarities of the transistors may be reversed. In addition, the number of columns of emitters 16 between base contacts 18 can be more or less than four.

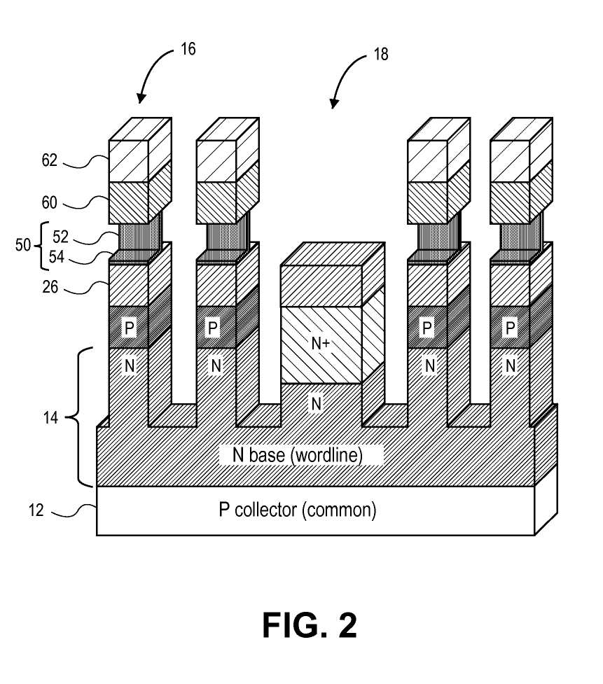

FIG. 2 is an isometric view of L-shaped heater elements disposed on a row of emitter pillars in the x-direction of a pnp-BJT array. The L-shaped heater elements 50 have a vertical wall 52 of which a width extends along the wordline direction, and a horizontal base 54 orthogonal to the wordline direction. The horizontal base 54 is in direct contact with the silicide contact region 26 on the emitter pillar 16. The vertical wall 52 and the horizontal base 54 may have approximately the same thickness. A phase change material 60, such as a chalcogenide, is in direct contact with the vertical wall 52 of the L-shaped heater element 50. A metallic cap 62 is formed on phase change material 60. As shown in FIG. 2, and as will become more apparent in the following figures, the phase change material 60 and L-shaped heater element 50 are self-aligned with the bitline direction of the phase change memory cell.

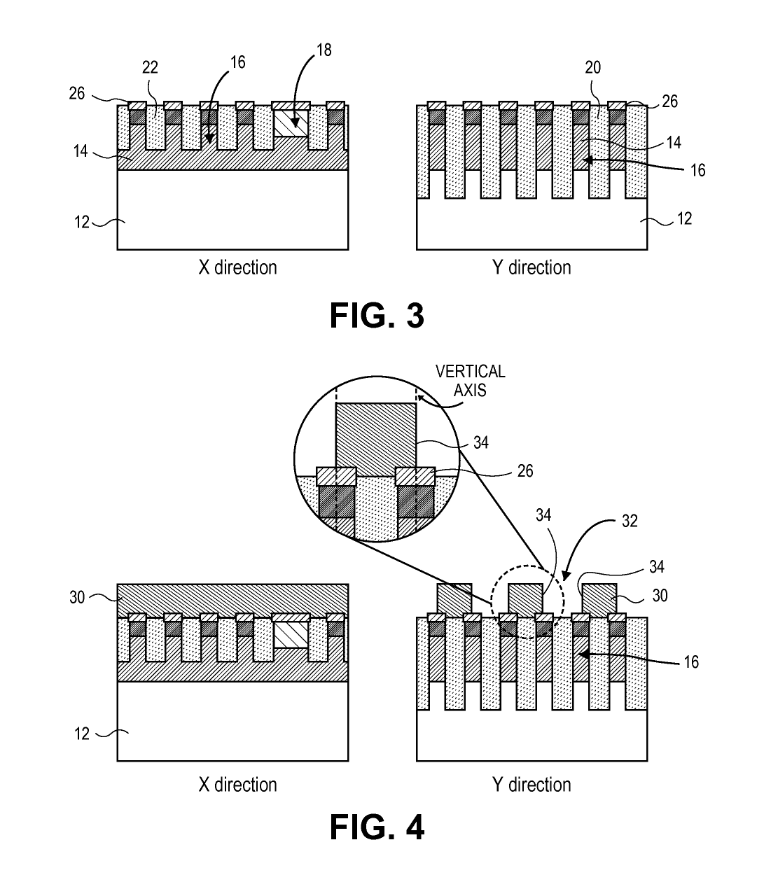

FIG. 3 is a cross-sectional illustration along the x-direction (parallel to the wordline direction) and the y-direction (parallel to the bitline direction) of the pnp-BJT array of FIG. 1. In an embodiment, each emitter pillar 16 has a width and depth of F×F, with F being the lithographic node. Emitters 16 are separated in the x-direction by shallow trench isolations 22 with a width of F, and in the y-direction by shallow trench isolations 20 with a width F. By way of example, the pnp-BJT array may be fabricated utilizing 193 nm immersion lithography, in which the width and depth of the pillars is approximately 50 nm, the height of the pillars along the x-direction is approximately 100 nm, and the height of the pillars along the y-direction is approximately 250 nm. The silicide 26 may comprise cobalt silicide, though other metal silicides may be used. in an embodiment where dimensions of the pnp-BJT array are larger than F, titanium silicide is utilized. In an embodiment where dimensions of the pnp-BJT array are smaller than F, nickel silicide is utilized. Embodiments are not limited to such dimensions determined by the lithographic node F.

As illustrated in FIG. 4, a dielectric layer 30 is then blanket deposited over the pnp-BJT array, patterned and anisotropically etched to form trenches 32. For example, dielectric layer 30 may be deposited utilizing conventional vapor deposition techniques such as chemical vapor deposition (CVD), and the trenches 32 may be formed utilizing conventional lithographic techniques. Dielectric layer 30 may be deposited to a thickness which is greater than the eventual height of the vertical heater elements because some of the thickness will be removed in a subsequent planarization operation. In an embodiment, dielectric layer 30 is between 50 and 200 nm thick. In an embodiment, dielectric layer 30 is silicon nitride, though other dielectric materials may be used.

In an embodiment, trenches 32 are formed with lateral sidewalls 34 approximately directly above the approximate center vertical axis of the emitter pillars 16 (and base pillars 18 not shown) in order to facilitate placement of the vertical wall 52 of heater element 50 directly above the center vertical axis of the emitter pillars 16. In such an embodiment, trenches 32 then have a width of 2F, or approximately 100 nm utilizing 193 nm immersion lithography. Though it is to be appreciated that such alignment is not required for the self-alignment process in accordance with embodiments of the invention. As will become more evident in the following figures, the width of trenches 32 can be wider or narrower in order to tailor both the placement of the vertical wall component 52 of the heater element 50 on the underlying silicide 26 of the emitter pillars 16, as well as the amount of contact the heater element 50 will have with the underlying silicide 26 of the emitter pillars 16. A wider trench 32 will result in a heater element 50 with a longer horizontal base component 54, with a narrower trench 32 resulting in a heater element 50 with a shorter or non-existent horizontal base component 54. In an embodiment, the trench sidewalls 32 terminate a minimum of 5 nm from the edges of the emitter pillars 16 (and base pillars 18 not shown) in order to ensure heater element 50 will be in direct contact with silicide 26.

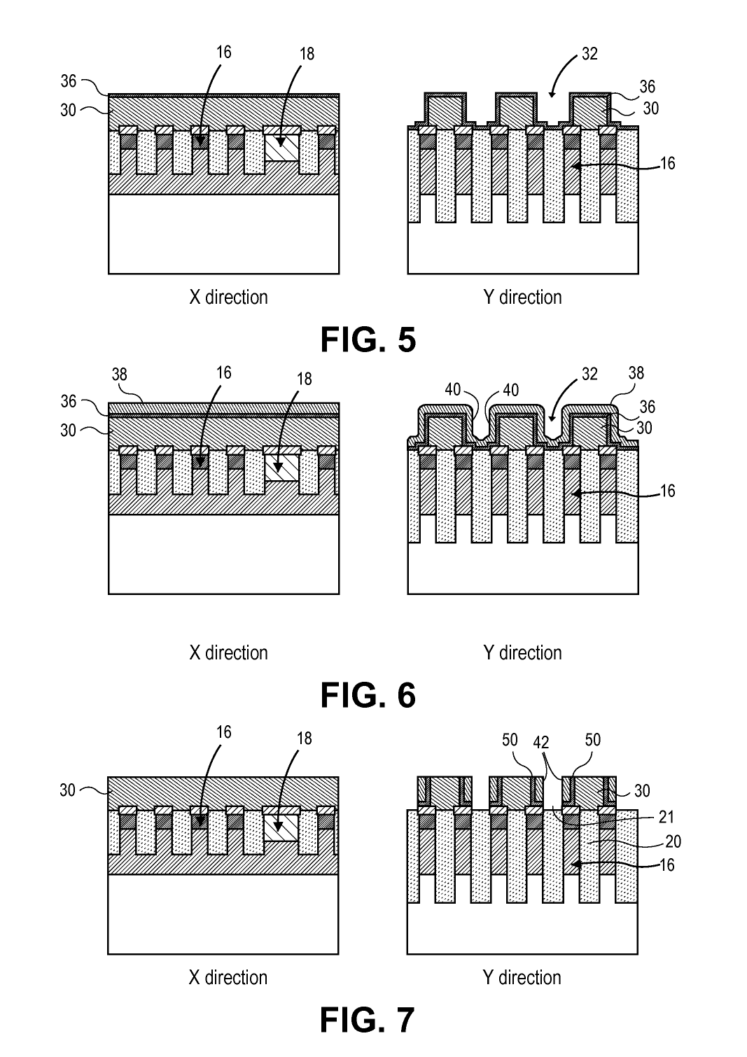

A conformal conductive layer 36, which is subsequently processed to form heater elements 50, is then deposited over the pnp-BJT array as illustrated in FIG. 5. Various conductive materials are available depending upon the electrical properties desired. In an embodiment, the conductive material may be a metal nitride (e.g., WN, TiN) or a metal nitride composite (e.g., WCN, TiAlN, TiSiN). Various conformal deposition techniques can be utilized such as chemical vapor deposition (CVD). Thickness of the conductive layer 36 is also dependent upon the electrical properties desired. In an embodiment, a metal nitride or metal nitride composite conformal conductive layer is between 3 and 15 nm thick on top of the dielectric layer 30 and within the trenches 32. The conformal conductive layer does not entirely fill the trench 32. Placement of the vertical wall component 52 of heater element 50 is determined by both the thickness of the conformal conductive layer 36, as well as placement and width of the trench 32. Thus, the vertical portion of conductive layer 36 formed in the trench 32 will become the vertical wall component 52 of heater element 50. In an embodiment, the vertical wall component 52 (i.e. vertical portion of conductive layer 36) is directly above the center vertical axis of an underlying emitter pillar 16. In such an embodiment, the horizontal base component 54 may have a length of approximately half of the width of the underlying emitter pillar 16. A conformal dielectric layer 38 is then deposited over the conformal conductive layer 36 as illustrated in FIG. 6. In an embodiment, dielectric layer 38 and dielectric layer 30 are formed of the same material to provide uniform removal during a subsequent etching and/or planarization operation. In an embodiment, dielectric layer 38 and dielectric layer 30 are formed of a nitride such as silicon nitride in order to protect the conductive layer 36 from oxidation during a subsequent planarization operation or deposition operation in oxidizing conditions. When the vertical portion of conductive layer 36 formed in the trench 32 is directly above the center vertical axis of an underlying emitter pillar 16, the thickness of conformal dielectric layer 38 may be approximately half of an underlying emitter pillar 16 width, or also approximately ½ F.

Conformal dielectric layer 38 and conformal conductive layer 36 are then anisotropically etched back with a standard dry etch chemistry to provide the structure in FIG. 7. As shown, conformal dielectric layer 38 and conformal conductive layer 36 are completely removed from the top surface of dielectric layer 30 and the top surface of the dielectric material 21 filling trenches 20 to form spacers 42 and vertical heater elements 50. In an embodiment, the thickness of the spacers 42 (i.e. vertical portion of dielectric layer 38) is not substantially etched during the anisotropic etching operation. By not substantially etched, it is intended that the remaining thickness of the vertical portion of dielectric layer 38 is approximately ½ F.

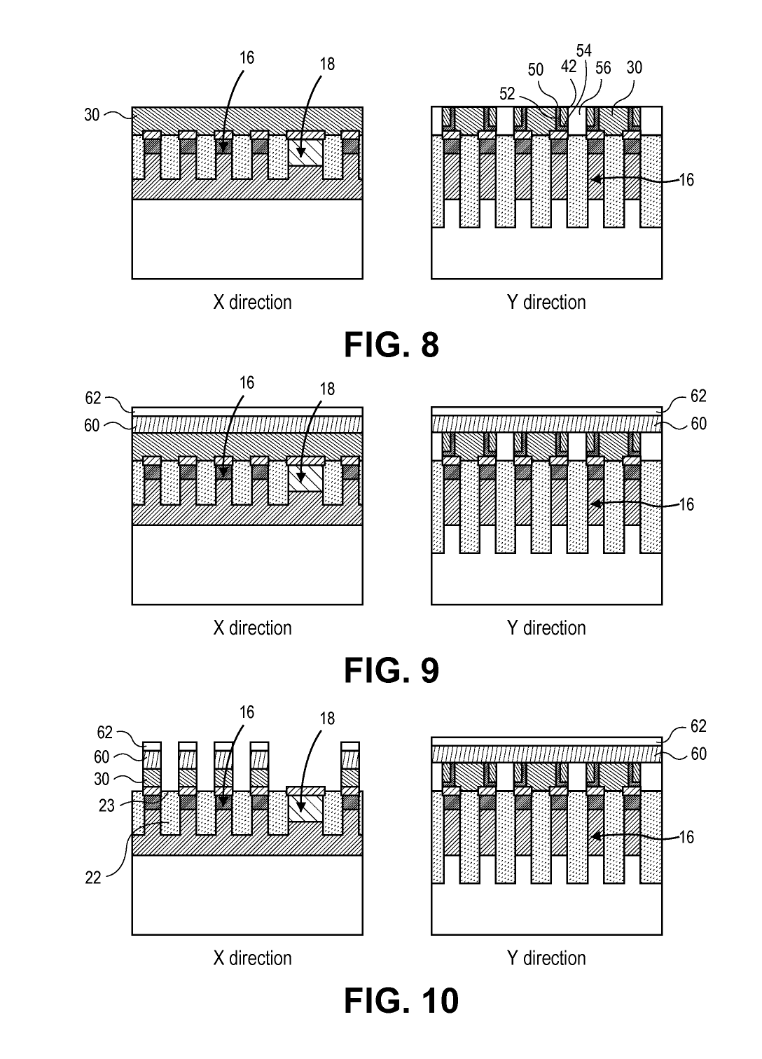

A dielectric layer 56 is then blanket deposited over the pnp-BJT array and within the trenches 32 and planarized as shown in FIG. 8. Dielectric layer 56 may be several hundred nm thick to fill the trenches 32. In an embodiment dielectric layer 56 is an oxide, such as silicon oxide. In an embodiment, planarization is performed with chemical mechanical polishing (CMP). As shown, the height of the vertical heater elements 50 and surrounding dielectric materials 30, 42, 56 may be reduced in this operation. In an embodiment, the planarized height of the vertical heater elements 50 is between 50 and 150 nm. In an embodiment, multiple dielectric layers can be used to fill the trenches 32.

As shown in FIG. 8, adjacent L-shaped heater elements 50 form repeating book-end configurations unique to embodiments of the invention. As shown, a first L-shaped heater element 50 may be facing a first direction, with a spacer 42 on the horizontal portion of the first L-shaped spacer. A second L-shaped heater element 50 adjacent the first L-shaped heater element is facing in a second direction opposite the first direction, with a spacer 42 on the horizontal portion of the second L-shaped heater element. As used herein, the direction the L-shaped heater element is facing is determined by the relationship of the horizontal base 54 and corresponding vertical wall 52, with the direction being in the plane of the horizontal base 54 orthogonal to the corresponding vertical wall 52. Where the vertical walls 52 of the first and second L-shaped heater elements 50 are on opposite sides of a patterned dielectric layer 30, and the first and second horizontal bases 54 are facing opposite directions, the first and second L-shaped heater elements 50 book-end the patterned dielectric layer 30 between the first and second vertical walls 52. It is to be appreciated that while the embodiment illustrated in FIG. 8 shows the vertical walls 52 directly above the center vertical axes of the underlying emitter pillars 16, the thickness of spacers 42 is approximately ½ F, and the spacers 42 are aligned with the sidewalls of the underlying emitter pillars 16 that such alignment is not required for the self-alignment process in accordance with embodiments of the invention.

A phase change layer 60, such as a chalcogenide, and metallic cap layer 62 are then blanket deposited over the pnp-BJT array as shown in FIG. 9. In an embodiment, the phase change layer 60 is deposited directly on the heater element 50 thereby avoiding the problem of alignment tolerances that may be found in other configurations in which a phase change material is deposited into a patterned trench. Selection of the phase change material will depend upon the particular device requirements and phases required. In an embodiment, a chalcogenide layer 60 is GST (Ge2Sb2Te5), and the corresponding metallic cap layer 62 is TiN. For example, a GST chalcogenide layer 60 may be deposited by PVD-sputtering and metallic cap layer 62 may be deposited with the same deposition technique. An additional metallic layer can be deposited on top of cap layer 62 in order to reduce the overall electrical resistance. The metallic cap layer 62, phase change layer 60, and dielectric layer 30 are then etched as lines (or trenches) that run parallel to the y-direction and in alignment with the rows of emitter pillars 16, and landing on the top surface of the dielectric material 23 of trenches 22 and silicide 26 of base pillars 18 as illustrated in FIG. 10. While not explicitly shown in FIG. 10, it is clear from the illustration that conductive layer 36 which forms the heater elements 50, dielectric layer 54, and spacers 42 are also etched in FIG. 10. Thus, the etching operation illustrated in FIG. 10 self-aligns the heater element 50 and phase change material 60 for each memory cell in the bitline direction, and separates adjacent heater elements 50 and phase change materials 60 in the wordline direction.

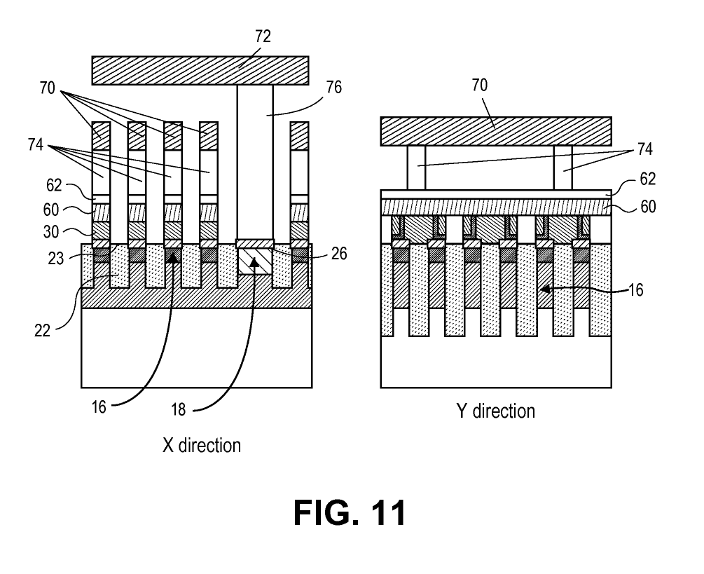

As shown in FIG. 11, a final back end of the line (BEOL) process is then added to form metal bitlines 70 parallel to the y-direction, metal wordlines 72 parallel to the x-direction and all required dielectric and metallization layers. For example, plugs 74 may connect metal bitline 70 to cap layer 62, and plug 76 may connect metal wordline 72 to silicide 26 of base contact 18.

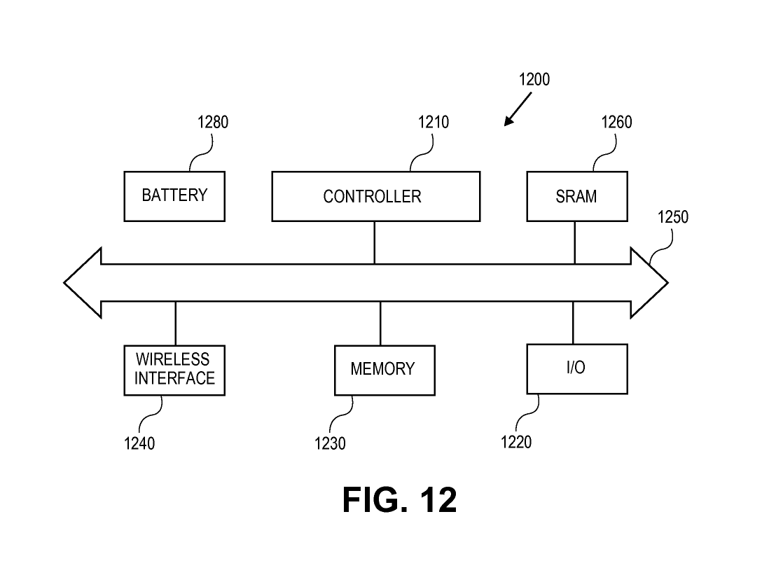

Turning to FIG. 12, a portion of a system 1200 in accordance with an embodiment of the present invention is described. System 1200 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 1200 may be used in any of the following systems: a wireless local area network (WLAN) system, a wireless personal area network (WPAN) system, a cellular network, although the scope of the present invention is not limited in this respect.

System 1200 may include a controller 1210, an input/output (I/O) device 1220 (e.g. a keypad, display), static random access memory (SRAM) 1260, a memory 1230, and a wireless interface 1240 coupled to each other via a bus 1250. A battery 1280 may be used in some embodiments. It should be noted that the scope of the present invention is not limited to embodiments having any or all of these components.

Controller 1210 may comprise, for example, one or more microprocessors, digital signal processors, microcontrollers, or the like. Memory 1230 may be used to store messages transmitted to or by system 1200. Memory 1230 may also optionally be used to store instructions that are executed by controller 1210 during the operation of system 1200, and may be used to store user data. Memory 1230 may be provided by one or more different types of memory. For example, memory 1230 may comprise any type of random access memory, a volatile memory, a non-volatile memory such as a flash memory and/or a memory discussed herein.

I/O device 1220 may be used by a user to generate a message. System 1200 may use wireless interface 1240 to transmit and receive messages to and from a wireless communication network with a radio frequency (RF) signal. Examples of wireless interface 1240 may include an antenna or a wireless transceiver, although the scope of the present invention is not limited in this respect.

In the foregoing specification, various embodiments of the invention have been described. It will, however, be evident that various modifications and changes may be made thereto without departing from the broader spirit and scope of the invention as set forth in the appended claims. The proposed cell architecture can be exploited with several other types of selecting elements such as silicon diode, MOSFET selector, OTS material, ZnO-based diode, binary-oxide diodes placed below the heater element or on top of the chalcogenide layer. Depending on the type of selector chosen, multi-stack array are also feasible. The specification and drawings are, accordingly, to be regarded in an illustrative sense rather than a restrictive sense. It is intended that the appended claims cover all such modifications and variations as fall within the true spirit and scope of this present invention.

What is claimed is:

1. A phase change memory cell comprising:
a pnp-BJT selection device;
a silicide contact region on an emitter of said pnp-BJT selection device;
an L-shaped vertical heater element extending along a wordline direction of said pnp-BJT selection device and in direct contact with said silicide contact region; and
a phase change material in direct contact with said L-shaped vertical heater element.

2. The phase change memory cell of claim 1, wherein said L-shaped vertical heater element is self-aligned with said phase change material extending along a bitline of said phase change memory cell.

3. The phase change memory cell of claim 2, wherein said emitter is an emitter pillar.

4. The phase change memory cell of claim 3, wherein said emitter pillar is part of a pnp-BJT array including plurality of emitter pillars shared by one base contact pillar.

5. The phase change memory cell of claim 2, wherein said L-shaped vertical heater element has a vertical wall and horizontal base with approximately the same thickness.

6. The phase change memory cell of claim 2, wherein said phase change material is a chalcogenide.

7. The phase change memory cell of claim 3, wherein said L-shaped vertical heater element includes a vertical wall directly above a center vertical axis of said emitter pillar.

8. The phase change memory cell of claim 7, wherein said L-shaped vertical heater element includes a horizontal base having a width of approximately half the width of said emitter pillar.

9. The phase change memory cell of claim 3, further comprising a spacer disposed on a horizontal base of said L-shaped vertical heater element, said spacer having a sidewall vertically aligned with a sidewall of said emitter pillar.

10. The phase change memory cell of claim 9, wherein said spacer has a width approximately half a width of said emitter pillar.

11. The phase change memory cell of claim 4, further comprising a second L-shaped vertical heater element, wherein said L-shaped vertical heater element is facing a first direction, and said second L-shaped vertical heater element is facing in a direction opposite the first direction.

12. A phase change memory array comprising:
a plurality of selection devices;
a silicide contact region on each of said plurality of selection devices;
a plurality of L-shaped vertical heater elements extending along a wordline direction of said phase change memory array and in direct contact with said plurality of silicide contact regions; and
a phase change material in direct contact with said plurality of L-shaped vertical heater elements;
wherein said plurality of L-shaped vertical heater elements are self-aligned with said phase change material extending along a bitline direction of said phase change memory array.

13. The phase change memory array of claim 12, wherein said plurality of L-shaped vertical heater elements are separated by an array of trenches extending along a wordline direction of said phase change memory array.

14. The phase change memory array of claim 13, wherein said selection devices are pnp-BJT devices.

15. A method of forming a phase change memory cell comprising:
depositing a first dielectric layer over a pnp-BJT selection device;
etching a trench in said first dielectric layer to expose a silicide contact region on an emitter of said pnp-BJT selection device;
depositing a conformal conductive layer on said first dielectric layer and in said trench and in direct contact with said silicide contact region;
depositing a second conformal dielectric layer on said conductive layer and in said trench, wherein said conductive layer and said second conformal dielectric layer do not entirely fill said trench;
anisotropically etching back said conductive layer and said second conformal dielectric layer on said first dielectric layer and in said trench; and
depositing a phase change material in direct contact with a top surface of said conductive layer.

16. The method of claim 15, further comprising:
depositing a third dielectric layer to completely fill said trench; and
planarizing to expose said first dielectric layer; and
depositing said phase change material in direct contact with said first dielectric layer, second conformal dielectric layer, third dielectric layer, and conductive layer.

17. The method of claim 16, further comprising etching back said phase change material and conductive layer to form an L-shaped heater element self-aligned with said phase change material in a bitline direction of said phase change memory cell.

18. The method of claim 15 further comprising:
etching a plurality of trenches in said first dielectric layer to expose a plurality of silicide contact regions on a plurality of emitters;
depositing said conformal conductive layer in said trenches;
depositing said second conformal dielectric layer on said conductive layer and in said trenches, wherein said conductive layer and said second conformal dielectric layer do not entirely fill said trenches; and
anisotropically etching back said conductive layer and said second conformal dielectric layer on said first dielectric layer and in said trenches.

19. The method of claim 18, further comprising:
depositing a third dielectric layer to completely fill said plurality of trenches; and
planarizing to expose said first dielectric layer; and
depositing a phase change material in direct contact with said first dielectric layer, second conformal dielectric layer, third dielectric layer, and conductive layer.

20. The method of claim 19, further comprising etching back said phase change material and said conductive layer in a plurality of lines running parallel to a wordline direction of said phase change memory cell to form an array phase change memory cells including L-shaped heater elements self-aligned with said phase change material in a bitline direction of said array phase change memory cells.
